(19) United States
(12) Patent Application Publication
(10) Pub. No.: US 2016/0056127 A1
(43) Pub. Date: Feb. 25, 2016

(54) SEMICONDUCTOR PACKAGE

(71) Applicant: Daeho Lee, Hwaseong-si (KR)

(72) Inventor: Daeho Lee, Hwaseong-si (KR)

(21) Appl. No.: 14/796,344

(22) Filed: Jul. 10, 2015

(30) Foreign Application Priority Data
Aug. 21, 2014 (KR) 10-2014-0109082

(51) Int. Cl. H01L 25/065; H01L 23/552; H01L 23/538; H01L 23/00; H01L 23/48

(52) U.S. Cl. CPC H01L 25/0657; H01L 24/49; H01L 23/481; H01L 23/5389; H01L 23/552

(57) ABSTRACT

A semiconductor package according to an embodiment of the inventive concept includes: a package substrate includes: a first through-hole disposed in a chip region; a second through-hole disposed in a edge region; a first bonding pad disposed on the edge region, the first bonding pad being adjacent to the first through-hole; and a second bonding pad disposed on the edge region, the second bonding pad being spaced apart from the first bonding pad, the second bonding pad being adjacent to the second through-hole, wherein one of a semiconductor chips disposed in the chip region is connected to the second bonding pad by a second bonding wire, and a second pattern connected to the second bonding pad is extended to the second through-hole.

### CROSS-REFERENCE TO RELATED APPLICATIONS

This U.S. non-provisional patent application claims priority under 35 U.S.C. §119 of Korean Patent Application No. 10-2014-0109082, filed on Aug. 21, 2014, the entire contents of which are hereby incorporated by reference.

### FIELD OF INVENTION

The present disclosure relates to a semiconductor package and, more particularly, to a semiconductor package having improved electrical characteristics.

### BACKGROUND

The number of input/output terminals of semiconductor packages is increased in order to improve the performance of the semiconductor packages. As a result, such semiconductor packages are highly dense. Consequently, an area required for a semiconductor substrate is increased, and thus the size of the semiconductor substrate is increased, causing an increase in the size of a semiconductor package. The increase in the size of the semiconductor package leads to an increase in the volume of the semiconductor package, so that a mounting area is increased. Increased mounting area is an undesirable consequence of such semiconductor packages.

### SUMMARY

The present disclosure provides a semiconductor package having a reduced size.

According to aspects of the inventive concept, provided is a semiconductor package including: a plurality of stacked semiconductor chips; a molding layer covering side surfaces of the semiconductor chips; and a package substrate including a chip region on which the semiconductor chips are mounted and an edge region covering a side surface of the molding layer, wherein the package substrate includes: a first through-hole disposed in the chip region; a second through-hole disposed in the edge region; a first bonding pad disposed on the edge region, the first bonding pad being adjacent to the first through-hole; and a second bonding pad disposed on the edge region, the second bonding pad being spaced apart from the first bonding pad, the second bonding pad being adjacent to the second through-hole, wherein one of the semiconductor chips is connected to the second bonding pad by a second bonding wire, and a second pattern connected to the second bonding pad is extended to the second through-hole.

In various embodiments, the other one of the semiconductor chips can be connected to the first bonding pad by a first bonding wire, and a first pattern connected to the first bonding pad can be extended to the first through-hole.

In various embodiments, the edge region of the package substrate can comprise an extended region and a bonding region disposed between the chip region and the extended region. The first bonding pad and the second bonding pad can be disposed on the bonding region, and the second through-hole can be disposed in the extended region.

In various embodiments, a lower surface of the molding layer can contact an upper surface of the bonding region of the package substrate, and the side surface of the molding layer can contact a side surface of the extended region of the package substrate.

In various embodiments, the extended region of the package substrate can comprise a first extended region and a second extended region. A side surface of the package substrate in the first extended region can contact the side surface of the molding layer, and an upper surface of the package substrate in the second extended region can be spaced apart from the side surface of the molding layer.

In various embodiments, a plane angle between an upper surface of the package substrate disposed in the bonding region and the side surface of the package substrate disposed in the first extended region can range from about 45° to about 135°, and a plane angle between the side surface of the package substrate disposed in the first extended region and the upper surface of the package substrate disposed in the second extended region can range from about 225° to 280°.

In various embodiments, an upper surface of the molding layer can cover the upper surface of the package substrate disposed in the second extended region.

In various embodiments, a plane angle between an upper surface of the package substrate disposed in the chip region and a side surface of the package substrate disposed in the edge region can range from about 45° to about 135°.

In various embodiments, the edge region of the package substrate can be extended onto an upper surface of the molding layer.

In various embodiments, an upper surface of the molding layer can have a width larger than that of a lower surface of the molding layer.

In various embodiments, the semiconductor package can further comprise a shielding layer disposed on a lower surface of the edge region of the package substrate.

In various embodiments, the second pattern can be electrically connected to the shielding layer through the second through-hole.

According to another aspect of the invention concept, provided is a semiconductor package comprising: a lower package, and an upper package comprising a plurality of upper semiconductor chips stacked on the lower package, an upper molding layer covering side surfaces of the upper semiconductor chips, and an upper package substrate having a chip region on which the upper semiconductor chips are mounted and an edge region covering a side surface of the upper molding layer, wherein the package substrate comprises: a first through-hole disposed in the chip region, a second through-hole disposed in the edge region, a first bonding pad disposed on the edge region, the first bonding pad being adjacent to the first through-hole, and a second bonding pad disposed on the edge region, the second bonding pad being spaced apart from the first bonding pad, the second bonding pad being adjacent to the second through-hole, wherein one of the upper semiconductor chips is connected to the second bonding pad by a second bonding wire, and a second pattern connected to the second bonding pad is extended to the second through-hole.

In various embodiments, the other one of the upper semiconductor chips can be connected to the first bonding pad by a first bonding wire, and a first pattern connected to the first bonding pad can be extended to the first through-hole.

In various embodiments, the semiconductor package can further comprise an interposer substrate disposed between the upper package substrate and the lower package substrate.

According to another aspect of the invention concept, provided is a semiconductor package, comprising: a substrate comprising a chip region formed between two bonding regions, which are formed between two extended regions; a plurality of stacked semiconductor chips in the chip region; a plurality of boding pads formed in the bonding regions; and a molding layer formed on the chip region and the boding regions, the molding layer covering side surfaces of the semiconductor chips, wherein the extended regions cover side surfaces of the molding layer.

In various embodiments, the substrate can be an upper package substrate, the semiconductor package can further comprise a lower package supporting the upper package substrate and comprising a lower package substrate having a plurality of external terminals and an interposer substrate disposed between the upper package substrate and the lower package substrate.

In various embodiments, the semiconductor package can further comprise a shielding layer disposed on sides of the extended region.

In various embodiments, a side surface of the extended region that contacts the molding layer can be sloped.

In various embodiments, a portion of the extended region can cover a portion of the molding layer

### BRIEF DESCRIPTION OF THE DRAWINGS

The accompanying drawings are included to provide a further understanding of the inventive concept, and are incorporated in and constitute a part of this specification. The drawings illustrate aspects of the inventive concept and, together with the description, serve to explain principles of the inventive concept. In the drawings:

FIG. 1 is a planar view illustrating an embodiment of a semiconductor package according to aspects of the inventive concept;

FIG. 2A is a cross-sectional view of a first embodiment of the semiconductor package of FIG. 1 taken along line I-I′ according to aspects of the inventive concept;

FIG. 2B is a magnified view of portion A of FIG. 2A;

FIG. 3A is a cross-sectional view of a second embodiment of the semiconductor package of FIG. 1 taken along line I-I′ according to aspects of the inventive concept;

FIG. 3B is a magnified view of portion B of FIG. 3A;

FIG. 4A is a cross-sectional view of a third embodiment of the semiconductor package of FIG. 1 taken along line I-I′ according to aspects of the inventive concept;

FIG. 4B is a cross-sectional view illustrating an upper package according to the third embodiment of FIG. 4A;

FIG. 4C is a magnified view of portion C of FIG. 4B;

FIG. 5 is a cross-sectional view of a fourth embodiment of the semiconductor package taken along line I-I′ of FIG. 1 according to aspects of the inventive concept;

FIG. 6 is a cross-sectional view of a fifth embodiment of the semiconductor package taken along line I-I′ of FIG. 1 according to aspects of the inventive concept;

FIG. 7 is a planar view illustrating an embodiment of a modified example of a semiconductor package, according to aspects of the inventive concept;

FIG. 8 is a cross-sectional view of the semiconductor package embodiment of FIG. 7 taken along line II-II′ according to aspects of the inventive concept;

FIG. 9 is a block diagram illustrating an example of an electronic device including an embodiment of a semiconductor package according to aspects of the inventive concept; and

FIG. 10 is a block diagram illustrating an example of a memory system including an embodiment of a semiconductor package according to aspects of the inventive concept.

### DETAILED DESCRIPTION OF THE EMBODIMENTS

Various exemplary embodiments in accordance with the inventive concept will be described below in more detail with reference to the accompanying drawings. The inventive concept may, however, be embodied in different fauns and should not be construed as being limited to the embodiments set forth herein. Like reference numerals refer to like elements throughout.

The terminology used herein is not for delimiting the embodiments of the inventive concept, but for describing the embodiments. The terms of a singular form may include plural forms unless otherwise specified or unless the context clearly indicates otherwise. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

It will be understood that, although the terms first, second, etc. are be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The embodiments of the inventive concept will be described with reference to exemplary cross-sectional views and/or planar views. In the drawings, the dimensions of layers and regions are exaggerated for clarity of illustration. As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. Therefore, the embodiments of the inventive concept may involve changes of shapes, without being limited to the illustrated specific forms. For example, an etching region illustrated as being angulated may have a shape that is rounded or has a predetermined curvature. As another example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Therefore, the regions illustrated in the drawings are merely schematic, and the shapes of the regions exemplify idealized shapes of the elements, but do not delimit the scope of the inventive concept.

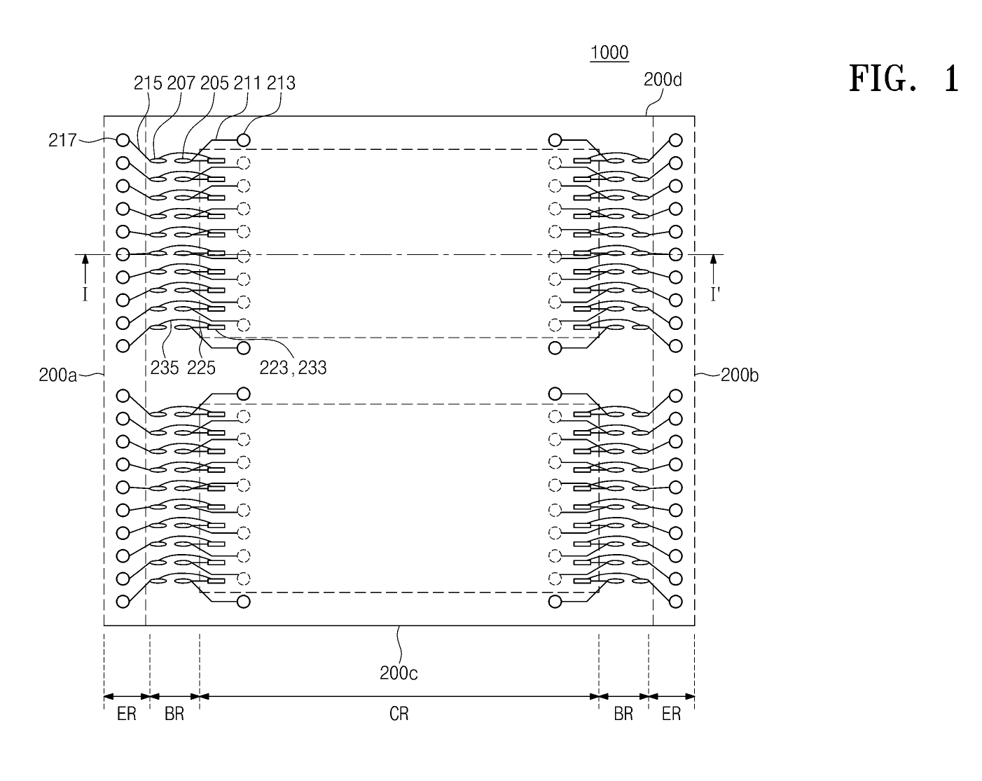

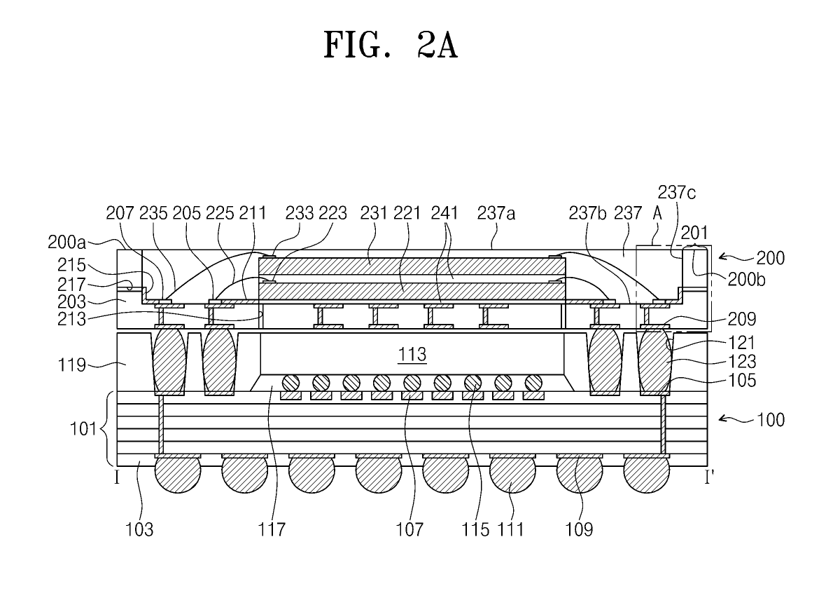

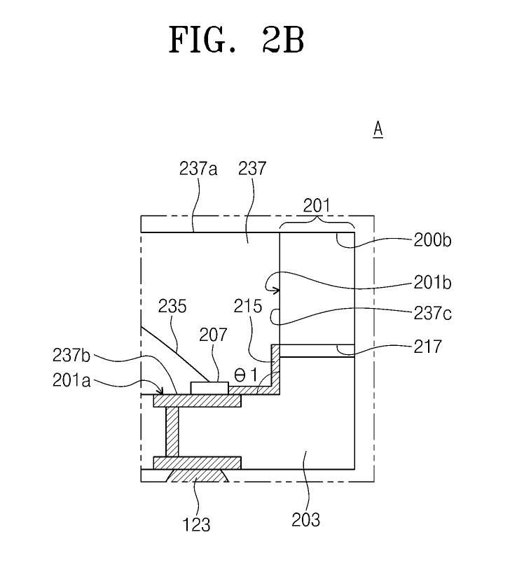

FIG. 1 is a planar view illustrating an embodiment of a semiconductor package according to aspects of the inventive concept. FIG. 2A is a cross-sectional view of a first embodiment of the semiconductor package of FIG. 1 taken along line I-I′ according to aspects of the inventive concept. FIG. 2B is a magnified view of the portion A of FIG. 2A.

Referring to FIGS. 1 and 2A, a semiconductor package 1000 includes a lower package 100 and an upper package 200. The lower package 100 may include a lower package substrate 101, a lower semiconductor chip 113, and a lower molding layer 119.

The lower package substrate 101 may be a multi-layered printed circuit board (PCB), for example. The lower package substrate 101 may include a plurality of insulation layers 103. An internal wiring (not illustrated) may be disposed between the insulation layers 103. A lower connection pad 105 may be disposed on an upper surface of an edge of the lower package substrate 101. Chip pads 107 may be disposed on an upper surface of an intermediate or center part of the lower package substrate 101. Ball lands 109 may be disposed on a lower surface of the lower package substrate 101. External terminals 111 may be bonded to the ball lands 109 respectively. The external terminals 111 provide a structural mechanism useful to electrically connect the semiconductor package 1000 to an external device.

The lower semiconductor chip 113 may be disposed on the chip pads 107. In this embodiment, the chip bumps 115 are bonded to the lower surface of the lower semiconductor chip 113. The chip bumps 115 may be correspondingly attached to the chip pads 107 so that the lower semiconductor chip 113 is electrically connected to the lower package substrate 101 by the chip bumps 115 and chip pads 107. The lower semiconductor chip 113 may be a logic device, such as a microprocessor or a memory device as examples. Alternatively, a part of the lower semiconductor chip 113 may be a memory device and another part of the lower semiconductor chip 113 may be a logic device, as another example.

An underfill resin layer 117 may be formed between the lower package substrate 101 and the lower semiconductor chip 113. The underfill resin layer 117 may fill a gap between the chip bumps 115. The lower molding layer 119 may be formed on the lower package substrate 101. The lower molding layer 119 may be formed to cover the upper surface of the lower package substrate 101 and a side surface of the lower semiconductor chip 113. The lower molding layer 119 may not cover an upper surface of the lower semiconductor chip 113. Therefore, the upper surface of the lower semiconductor chip may remain exposed.

The lower molding layer 119 may include a connection through-hole 121 that exposes the lower connection pad 105. The connection through-hole 121 may be tapered, as in this embodiment. For example, an upper width of the connection through-hole 121 may be larger than a bottom width of the connection through-hole 121. An electrically conductive connection terminal (or material) 123 may be disposed in the connection through-hole 121.

The upper package 200 may include an upper package substrate 201, upper semiconductor chips and an upper molding layer 237.

The upper package substrate 201 includes bonding regions BR, a chip region CR that is disposed between the bonding regions BR and is adjacent to one side of each of the bonding regions BR, and extended regions ER adjacent to the other side of each of the bonding regions BR. As such, each bonding region BR may be disposed between the chip region CR and an extended region ER. The upper package substrate 201 may include or be formed from a flexible material bendable to a desired shape. The upper package substrate 201 may be or include one of a printed circuit board, a flexible substrate, and/or a tape substrate, for example. The upper package substrate 201 may be formed in a copper clad laminate having at least two layers. For example, copper pads and patterns may be formed in an upper layer and a lower layer of the upper package substrate 201. A core layer 203 including an insulating material may be disposed between the upper layer and the lower layer.

A first bonding pad 205 and a second bonding pad 207 may be spaced apart from each other and may be disposed on the bonding regions BR of the upper package substrate 201. The second bonding pad 207 may be farther away from the chip region CR of the upper package substrate 201 than the first bonding pad 205.

One or more upper semiconductor chips may be mounted on the chip region CR of the upper package substrate 201. In detail, the upper semiconductor chips may include one or more first upper semiconductor chips 221 and one or more second semiconductor chips 231. An adhesive layer 241 may be disposed between the upper package substrate 201 and a first upper semiconductor chip 221 so that the first upper semiconductor chip 221 is bonded to an upper surface of the upper package substrate 201.

The first upper semiconductor chip 221 and a second upper semiconductor chip 231 may each be a memory chip or a logic chip. The first upper semiconductor chip 221 and the second upper semiconductor chip 231 may be homogeneous or heterogeneous products. For example, all the first upper semiconductor chips 221 may be memory chips, and all the second upper semiconductor chips 231 may be logic chips. The number of the first upper semiconductor chips 221 and the number of the second upper semiconductor chips 231 are exemplarily illustrated and do not limit the scope of the present embodiment.

A first chip pad 223 may be disposed on an upper surface of the first upper semiconductor chip 221. The first chip pad 223 may be disposed on an edge of the first upper semiconductor chip 221. The first chip pads 223 may be respectively connected by first bonding wires 225 to the first bonding pads 205 disposed on adjacent bonding regions BR of the upper package substrate 201.

A first pattern 211 may be connected to the first bonding pad 205 by a transmission path. The first pattern 211 may be at least one of a signal transferring pattern, a power pattern, and a grounding pattern of the first upper semiconductor chip 221 formed on the upper package substrate 201. In the present embodiment, the first pattern 211 is assumed to be a signal transferring pattern. The first pattern 211 may be connected to an upper connection pad 209 formed on the lower layer of the upper package substrate 201 through a first through-hole 213 formed in the chip region CR of the upper package substrate 201. The first pattern 211 may one-to-one correspond to the first through-hole 213. The first through-hole 213 may penetrate the core layer 203, e.g., extending completely through the core layer 203.

The second upper semiconductor chip 231 may be stacked on the first upper semiconductor chip 221. The adhesive layer 241 may be disposed between the first upper semiconductor chip 221 and the second upper semiconductor chip 231 so that the second upper semiconductor chip 231 may be bonded onto the first upper semiconductor chip 221. A second chip pad 233 may be disposed on an upper surface of the second upper semiconductor chip 231. The second chip pad 233 may be disposed on an edge of the second upper semiconductor chip 231. The second chip pads 233 may be respectively connected by second bonding wires 235 to the second bonding pads 207 disposed on adjacent bonding regions BR of the upper package substrate 201. The second through-hole 217 may penetrate the core layer 203, e.g., extending completely through the core layer 203.

A second pattern 215 may be connected to the second bonding pad 207. The second pattern 215 may be at least one of a signal transferring pattern, a power pattern, and a grounding pattern of the second upper semiconductor chip 231 formed on the upper package substrate 201. In the present embodiment, the second pattern 215 is assumed to be a signal transferring pattern. The second pattern 215 may be connected to the upper connection pad 209 formed on the lower layer of the upper package substrate 201 through the second through-hole 217 formed in the extended region ER of the upper package substrate 201. The second pattern 215 may one-to-one correspond to the second through-hole 217, as shown in FIG. 1. The second through-hole 217 may be adjacent to a first surface 200a and a second surface 200b of the upper package substrate 201. That is, the second pattern 215, second bonding pads 207, first bonding pads 205, first pattern 211, and first though-holes 213 and so on may be the same near second surface 200b as near the first surface 200a.

The upper molding layer 237 may be formed on the upper package substrate 201. The upper molding layer 237 may cover the first and second upper semiconductor chips 221 and 231. The upper package substrate 201 may cover sides 237c of the upper molding layer 237. In detail, at a location where the bonding region BR and the extended region ER of the upper package substrate 201 meet, the upper package substrate 201 may be bent so that the extended regions ER of the upper package substrate 201 cover the sides 237c of the upper molding layer 237. That is, as shown in FIGS. 2A and 213, the extended regions ER of the upper package substrate 201 may form vertical walls (or sidewalls) with respect to the relative horizontal bonding region BR. The overall shape of the upper package substrate 201 may be considered to have a central depression or trough between the extended regions ER. And, in this embodiments, the first upper semiconductor chip 221 and the second upper semiconductor chip 231 are disposed within the central depression in a stacked configuration so that a top surface of the second upper semiconductor chip 231 is below a top surface of the extended regions ER. Therefore, the second through-hole 217 may contact the sides 237c of the upper molding layer 237.

Referring to FIG. 2B, a plane angle θ1 between an upper surface 201a of the upper package substrate 201 of the bonding regions BR and an side surface 201b of the upper package substrate 201 of the extended regions ER may range from about 45° to about 90°. Therefore, a plane angle between a lower surface 237b and an inner side 237c of the upper molding layer 237 may be equal to the plane angle θ1. An upper surface 237a of the upper molding layer 237 may have a width that is smaller than or equal to that of the lower surface 237b of the upper molding layer 237. For example, if the side surface 201b and the inner side 237c are angled so that θ1 is less than 90 degrees, then the upper surface 237a of the upper molding layer 237 may have a width that is smaller than that of the lower surface 237b of the upper molding layer 237. The upper surface 237a of the upper molding layer 237 may be coplanar with the first and second surfaces 200a and 200b of the upper package substrate 201, see also FIG. 2A.

The upper connection pad 209 formed on the lower layer of the upper package substrate 201 may contact the connection terminal 123. Accordingly, the upper package substrate 201 may be electrically connected to the lower package substrate 101. As a result, the first and second patterns 211 and 215 may be connected to the external terminals 111 through the connection terminal 123. One external terminal 111 may be electrically connected to one signal transferring pattern, as an example.

As the performance of a semiconductor package is improved, each of the connection patterns (e.g., signal patterns or power patterns) formed in the semiconductor package is connected to one external terminal. For example, the chip pads 223 and 233 formed on semiconductor chips 221, 231 are respectively connected to the bonding pads 205 and 207 on a package substrate by wire bonding, in this embodiment, and the connection patterns respectively connected to the bonding pads are connected to external terminals through the through-holes 213 and 217. The number of bonding pads and the through-holes formed in the package substrate may be the same as the number of the chip pads, and the numbers of the bonding pads and the through-holes are increased as the number of stacked semiconductor chips is increased. In addition, in the case where two or more semiconductor chips are stacked, the pitch of the bonding pads is decreased as the number of bonding pads is increased. Therefore, the connection patterns respectively connected to the semiconductor chips may be disposed in different directions. Accordingly, the package substrate is increased in size, causing an increase in the size of the semiconductor package. In addition, in the case where the semiconductor package having an increased size is used as an upper package in a semiconductor package structure in which two packages are stacked, the upper package is larger than a lower package. Therefore, the mounting of passive elements at the periphery of the semiconductor package is limited, and an edge of the upper package is vulnerable to an external impact.

In one embodiment in accordance with the inventive concept, after the upper molding layer 237 is formed on the upper package substrate 201, the extended regions ER of the upper package substrate 201 may be folded, patterned, or otherwise shaped to form sides that the extended regions ER are positioned on the sides 237c of the upper molding layer 237. In such embodiments, the ERs may form sidewalls. Therefore, a space for the second pattern 215 and the second through-hole 217 may be provided in the upper package substrate 201, so that the semiconductor package 1000 may be prevented from being increased in size.

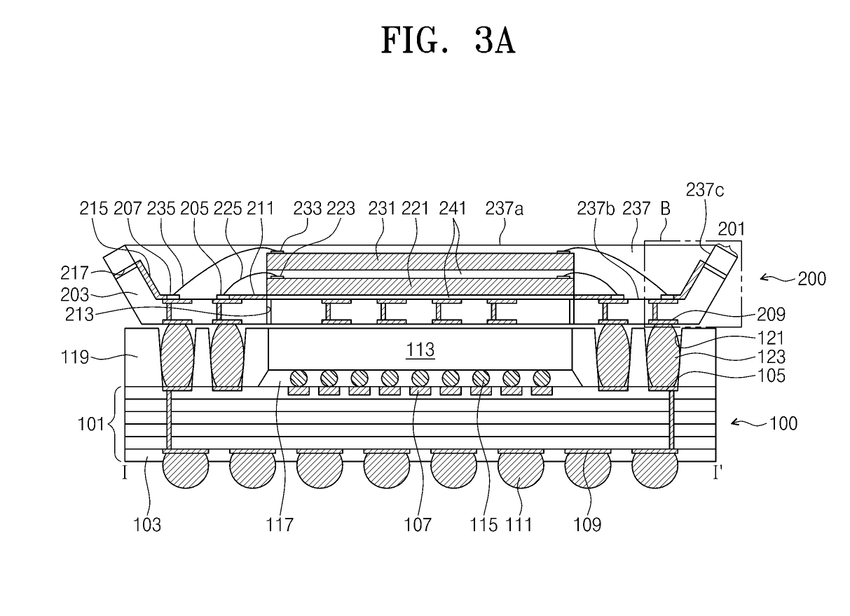

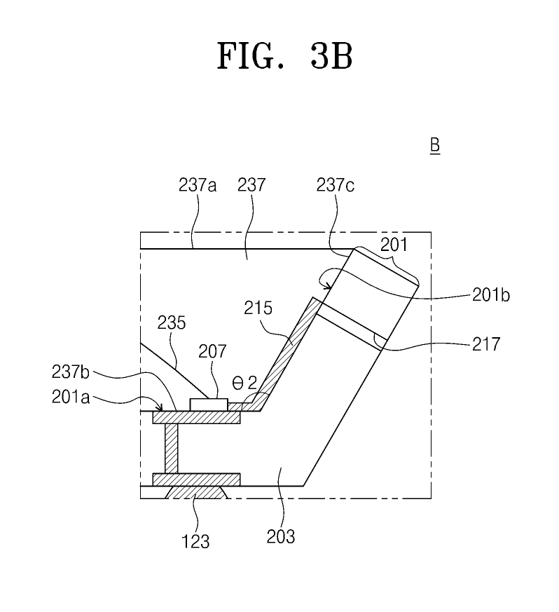

FIG. 3A is a cross-sectional view of a second embodiment of the semiconductor package of FIG. 1 taken along line I-I′, according to aspects of the inventive concept. FIG. 3B is a magnified view of the portion B of FIG. 3A. Features of FIGS. 3A and 3B that are the same as those already described will not be described again with respect to FIGS. 3A and 3B, to avoid repetitive description.

Referring to the embodiment of FIGS. 3A and 3B, the extended regions ER of the upper package substrate 201 may be formed to cover the sides 237c of the upper molding layer 237. A plane angle θ2 between the upper surface 201a of the upper package substrate 201 of the bonding regions BR and the side surface 201b of the upper package substrate 201 of the extended regions ER may range from about 90° to about 180°, more specifically, the range can be from about 90° to about 135°. Therefore, the plane angle between the lower surface 237b and the sides 237c of the upper molding layer 237 may be equal to the plane angle θ2. That is, the side surfaces of the extended regions can be sloped, rather than 90 degrees.

The lower surface 237b of the upper molding layer 237 may have a width that is larger than or equal to that of the upper surface 237a of the upper molding layer 237.

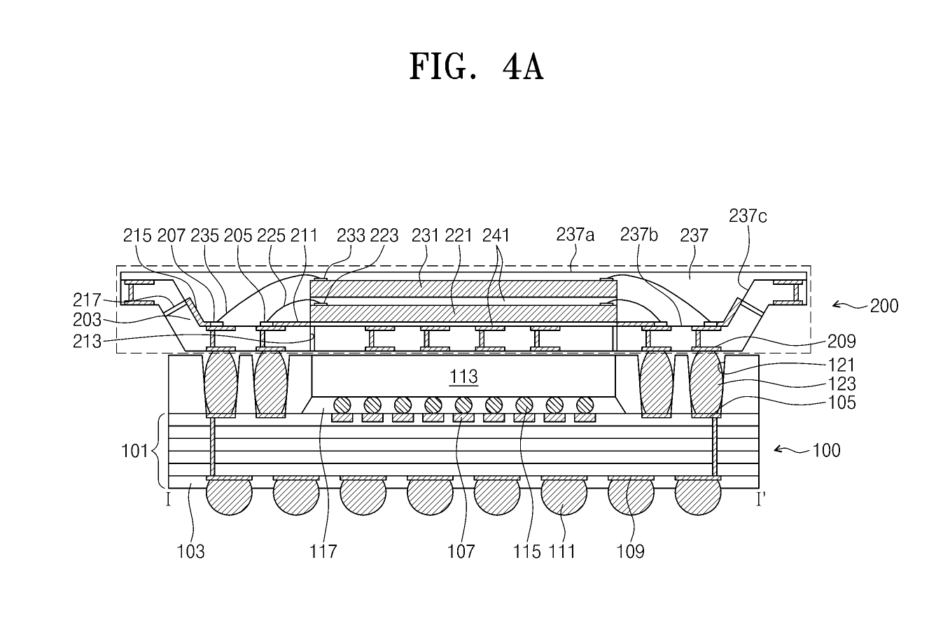

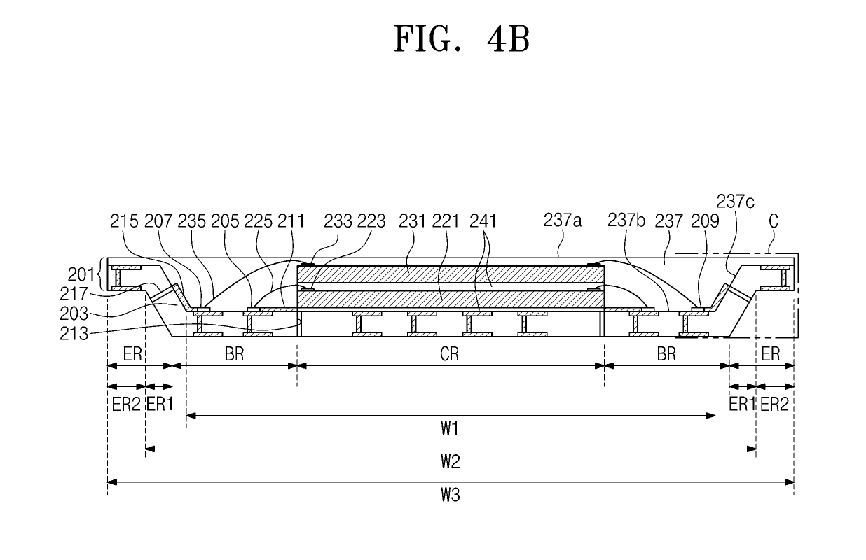

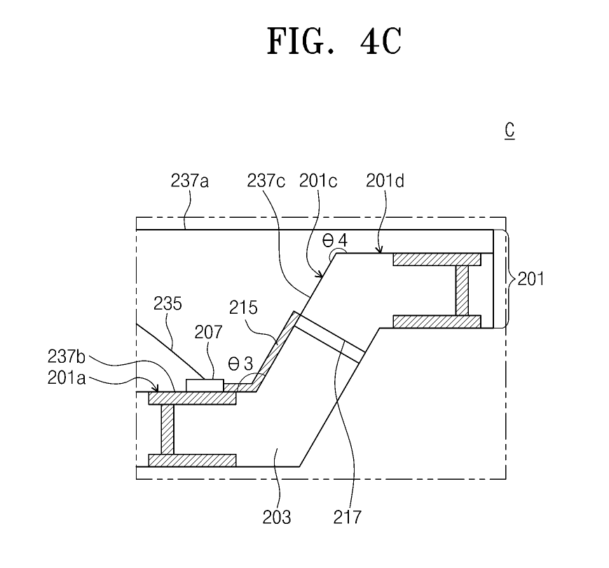

FIG. 4A is a cross-sectional view of a third embodiment of the semiconductor package of FIG. 1 taken along line I-I′, according to aspects of the inventive concept. FIG. 4B is a cross-sectional view illustrating an upper package according to the third embodiment. FIG. 4C is a magnified view of the portion C of FIG. 4B. Features of FIGS. 4A through 4C that are the same as those already described will not be described again with respect to FIGS. 4A through 4C, to avoid repetitive description.

Referring to the embodiment of FIGS. 4A to 4C, the extended regions ER of the upper package substrate 201 may include a first extended region ER1 and a second extended region ER2. The first extended region ER1 may be disposed between the bonding region BR and the second extended region ER2. Accordingly, the second extended region ER2 may be disposed at an outermost region of the upper package substrate 201.

A plane angle θ3 between the upper surface 201a of the upper package substrate 201 of the bonding regions BR and a side surface 201c of the upper package substrate 201 of the first extended region ER1 may range from about 90° to about 180°, more specifically, from about 90° to about 135° in this embodiment. Furthermore, a plane angle θ4 between the side surface 201c of the upper package substrate 201 of the first extended region ER1 and an upper surface 201d of the upper package substrate 201 of the second extended region ER2 may range from about 180° to about 280°, more specifically, from about 225° to about 280° in this embodiment.

The upper molding layer 237 may be formed on the upper package substrate 201. The upper molding layer 237 may be formed to cover the upper surface 201a of the bonding regions BR and the side surface 201c and the upper surface 201d of the extended regions ER of the upper package substrate 201. The upper surface 237a of the upper molding layer 237 may have a width that is larger than that of the lower surface 237b of the upper molding layer 237. For example, referring to FIG. 4B, a width W1 of the lower surface 237b of the upper molding layer 237, which contacts the upper surface 201a of the chip region CR and bonding regions BR of the upper package substrate 201, may be smaller than a width W2 of the upper molding layer 237 between the sides 237c thereof which contact the side surface 201c of the first extended region ER1 of the upper package substrate 201. And the width W2 of the upper molding layer 237 between the sides 237c thereof may be smaller than a width W3 of the upper surface 237a of the upper molding layer 237.

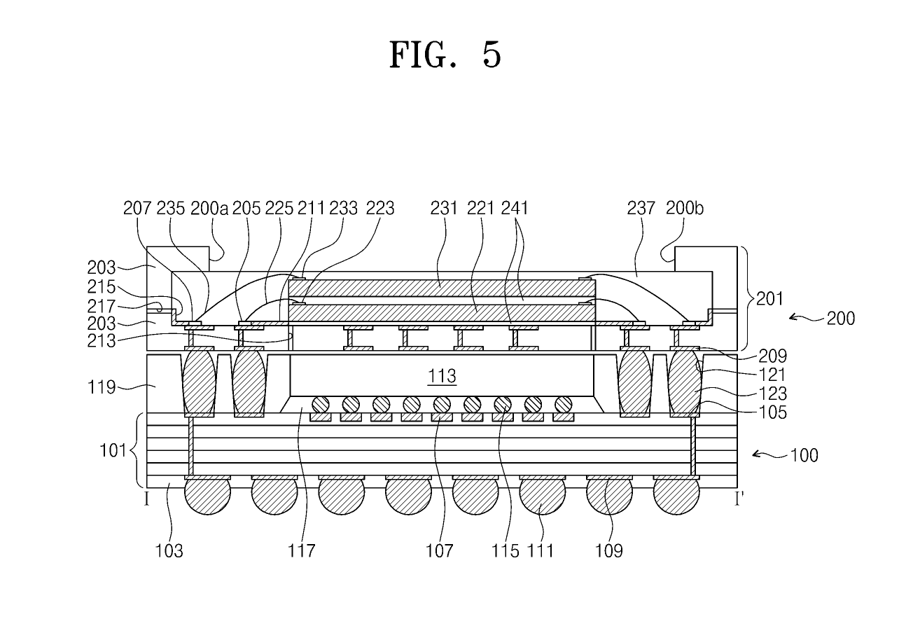

FIG. 5 is a cross-sectional view of a fourth embodiment of the semiconductor package of FIG. 1 taken along line I-I′, according to aspects of the inventive concept. Features of FIG. 5 that are the same as those already described will not be described again with respect to FIG. 5, to avoid repetitive description.

Referring to the embodiment of FIG. 5, the extended regions ER of the upper package substrate 201 may cover the sides 237c of the upper molding layer 237, and may be extended to the upper surface 237a to cover a part of the upper surface 237a of the upper molding layer 237. A first surface 200a and a second surface 200b of the upper package substrate 201 may be disposed on the upper surface 237a of the upper molding layer 237, while being spaced apart from each other.

Referring back to FIG. 1, the upper package substrate 201 includes a third surface 200c and a fourth surface 200d, wherein the third surface 200c may be opposite the fourth surface 200d. Although not illustrated in the drawings, for example, at least one of the third surface 200c and the fourth surface 200d of the upper package substrate 201 may be coplanar with the upper surface 237a of the upper molding layer 237, while the extended regions ER of the upper package substrate 201 cover the sides 237c of the upper molding layer 237. For another example, at least one of the third surface 200c and the fourth surface 200d of the upper package substrate 201 may be disposed on the upper molding layer 237, while the extended regions ER of the upper package substrate 201 cover the sides 237c of the upper molding layer 237. Accordingly, the upper package substrate 201 may cover one to four sides of the upper molding layer 237.

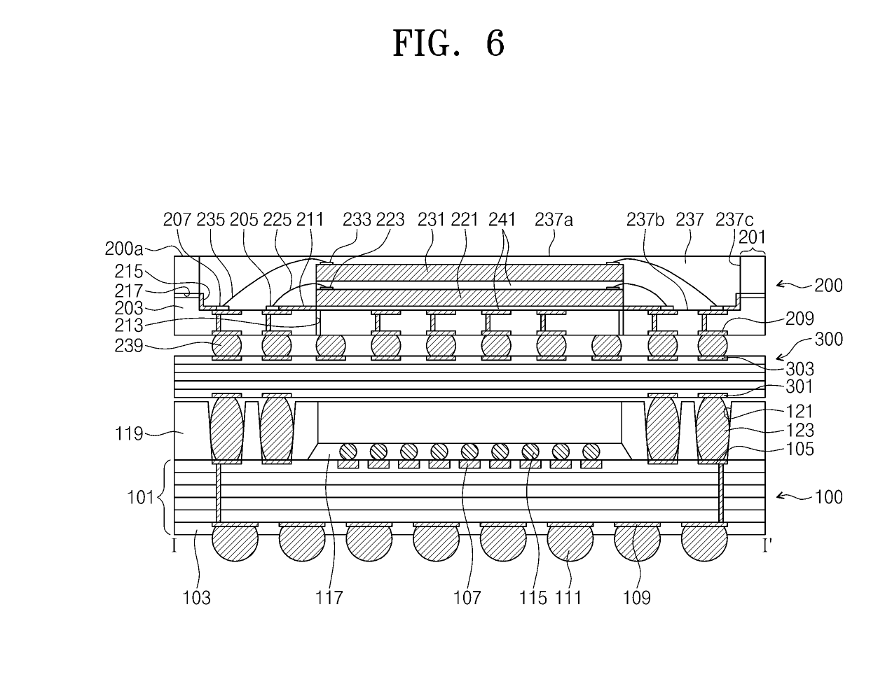

FIG. 6 is a cross-sectional view of a fifth embodiment of the semiconductor package of FIG. 1 taken along line I-I′, according to aspects of the inventive concept. Features of FIG. 6 that are the same as those already described will not be described again with respect to FIG. 6, to avoid repetitive description.

Referring to the embodiment of FIG. 6, an interposer substrate 300 may be provided between the lower package 100 and the upper package 200. The interposer substrate 300 may be a multi-layered PCB, for example. In detail, the interposer substrate 300 may include a plurality of interposer substrate insulating layers (not illustrated) and interposer substrate metal wirings (not illustrated) disposed between the interposer substrate insulating layers.

At least one first pad 301 may be disposed on a lower surface of the interposer substrate 300, and at least one second pad 303 may be disposed on an upper surface of the interposer substrate 300. The first pad 301 may contact the connection terminal 123. A solder ball 239 may be bonded onto the upper connection pad 209 of the upper package substrate 201. The solder ball 239 may contact the second pad 303.

The first pattern 211 may be connected to the solder ball 239 through the first through-hole 213, and the second pattern 215 may be connected, through the second through-hole 217, to another solder ball 239 that is not connected to the first pattern 211.

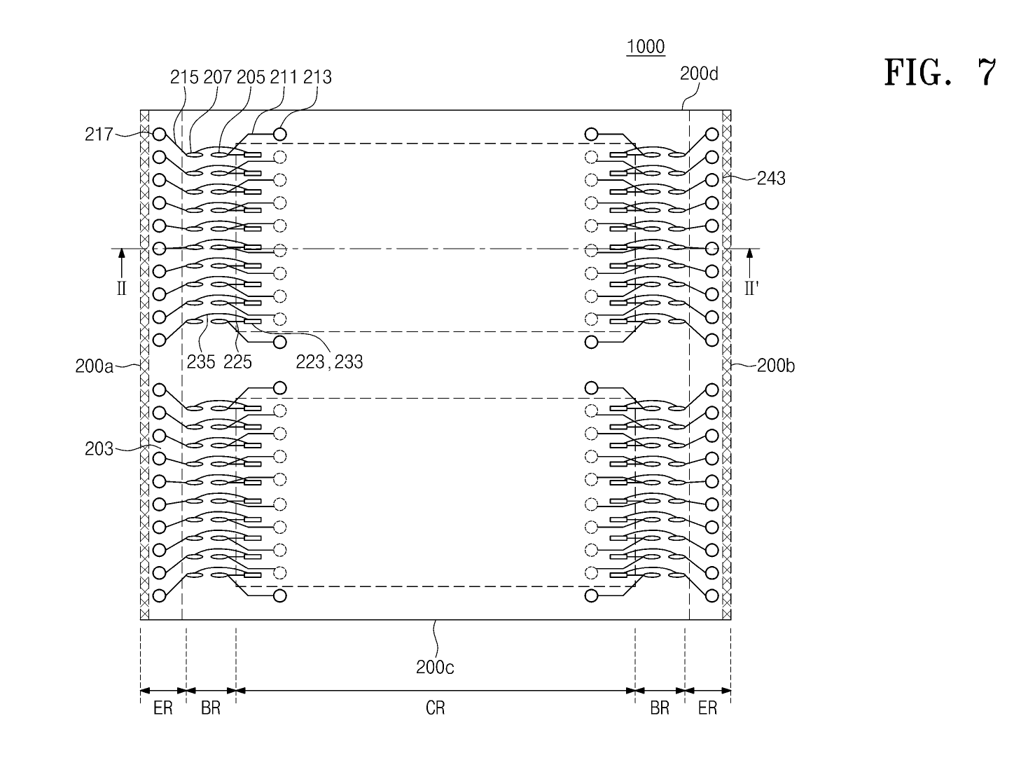

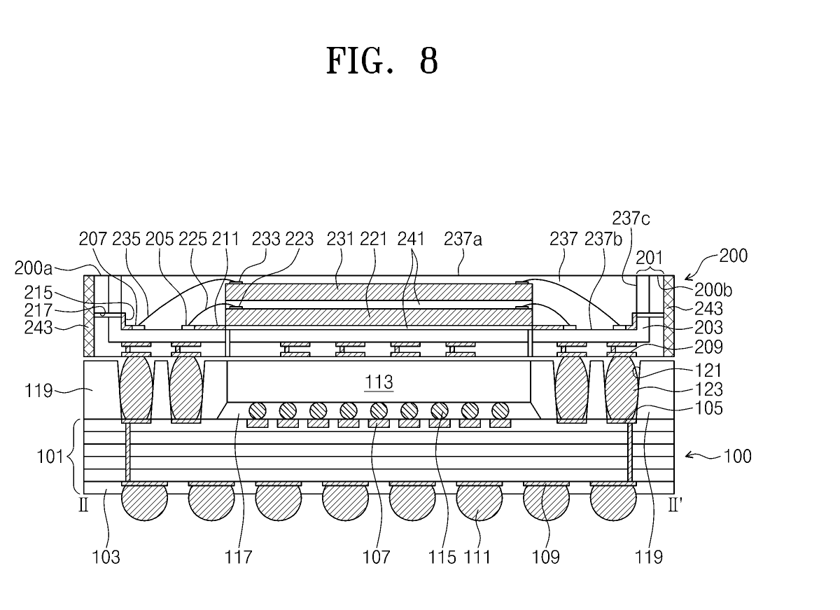

FIG. 7 is a planar view illustrating a sixth embodiment of a semiconductor package, according to aspects of the inventive concept. FIG. 8 is a cross-sectional view of the semiconductor package of FIG. 7 taken along line II-II′ according to aspects of the inventive concept.

Referring to the embodiment of FIGS. 7 and 8, the upper package substrate 201 may be formed as a copper clad laminate having at least three layers. For example, the upper package substrate 201 may include two core layers 203, and copper pads and patterns may be formed in an upper layer, a lower layer, and an intermediate layer disposed between the core layers 203 of the upper package substrate 201.

The second pattern 215 may be at least one of a signal transferring pattern, a power pattern and a grounding pattern of the second upper semiconductor chip 231 formed on the upper package substrate 201. In the case where the second pattern 215 is a signal transferring pattern, the second pattern 215 may be connected to a connection pattern (not illustrated) formed in the intermediate layer through the second through-hole 217 formed in the extended regions ER of the upper package substrate 201, and may be connected to the upper connection pad 209 formed on the lower layer in the bonding regions BR of the upper package substrate 201. In the case where the second pattern 215 is a grounding pattern, the second pattern 215 may contact a shielding layer 243 formed on the lower layer in the extended regions ER of the upper package substrate 201, through the second through-hole 217. That is, the shielding layer 243 may be formed on sides, e.g., vertical sides, of the extended regions of the upper package substrate 201. The shielding layer 243 may include a metal material such as copper (Cu), tungsten (W), or aluminum (Al). The shielding layer 243 may be a substantially vertical layer.

A semiconductor package to which the shielding layer 243 is applicable is not limited as illustrated in the drawings. For example, the shielding layer 243 may be applied to a semiconductor package including a semiconductor chip that is flip-chip-bonded to a package substrate using a solder ball, or may be applied to a semiconductor chip in which a single chip is stacked.

The shielding layer 243 may be chosen and configured to shield electromagnetic interference (EMI) due to electromagnetic radiation emitted from sides of the first and second upper semiconductor chips 221 and 231. Furthermore, a grounding pattern in the second pattern 215 may be directly contacted with the shielding layer 243 so that the shielding layer 243 may also serve as a grounding electrode. Accordingly, the extended regions ER of the upper package substrate 201 may be used as spacers for both a signal transferring pattern and a grounding electrode.

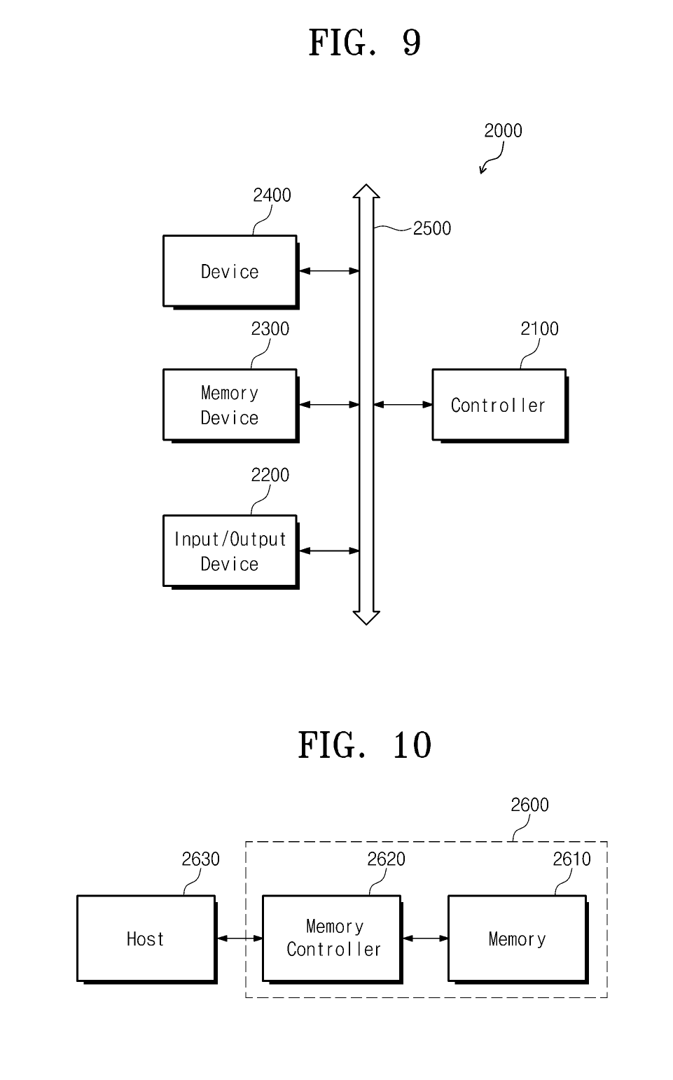

FIG. 9 is a block diagram illustrating an embodiment of an electronic device including a semiconductor package according to aspects of the inventive concept. FIG. 10 is a block diagram illustrating an embodiment of a memory system including a semiconductor package according to aspects of the inventive concept.

Referring to the embodiment of FIG. 9, an electronic system 2000 may include a controller 2100, an input/output device 2200, and a memory device 2300. The controller 2100, the input/output device 2200, and the memory device 2300 may be connected to each other via a bus 2500. The bus 2500 may be at least one medium through which data passes. For example, the controller 2100 may include at least one microprocessor, a digital signal processor, a microcontroller, and at least one of logic elements capable of performing the same functions as those of the microprocessor, the digital signal processor, and the microcontroller. The controller 2100 and the memory device 2300 may include an embodiment of the semiconductor package 1000 described herein, according to aspects of the inventive concept. The input/output device 2200 may include at least one device selected from any known input devices, as examples, a keypad, a keyboard, a mouse, and a touchscreen or other interactive display device. The memory device 2300 is configured to store data. The memory device 2300 may include data and/or commands executed by the controller 2100. The memory device 2300 may include or be a volatile memory device and/or a nonvolatile memory device. Alternatively, the memory device 2300 may include or be a flash memory device. For example, a flash memory to which the technology of the inventive concept is applied may be installed in an information processing system, such as a mobile device or a desktop computer. Such a flash memory may constitute a solid state drive (SSD). In this case, the electronic system 2000 may stably store a large amount of data in a flash memory system. The electronic system 2000 may further include an interface 2400 for transmitting/receiving data to/from a communication network. The interface 2600 may be operated by wire or wirelessly, or a combination thereof. For example, the interface 2600 may include an antenna and/or a wired/wireless transceiver. Furthermore, it would be apparent to those skilled in the art, having the benefit of this disclosure, that the electronic system 2000 may be further provided with an application chipset, a camera image processor (CIS), and an input/output device which are not illustrated in the drawings.

The electronic system 2000 may be implemented as a mobile system, a personal computer, an industrial computer, or a logic system for performing various functions. For example, the mobile system may be one of a personal digital assistant (PDA), a portable computer, a web tablet, a mobile phone, a wireless phone, a laptop computer, a memory card, a digital music system, and an information transmitting/receiving system. In the case where the electronic system 2000 is equipment for performing wireless communication, the electronic system 2000 may be used for a communication interface protocol of a third generation communication system, as examples, CDMA, GSM, NADC, E-TDMA, WCDMA or CDMA 2000.

FIG. 10 is a block diagram illustrating an example of a memory system including an embodiment of a semiconductor package according to aspects of the inventive concept.

Referring to the embodiment of FIG. 10, a memory card 2600 may include a nonvolatile memory device 2610 and a memory controller 2620. The nonvolatile memory device 2610 and the memory controller 2620 may store data or may read stored data. The nonvolatile memory device 2610 may include the semiconductor package 1100 according to an embodiment of the inventive concept. The memory controller 2620 may control the nonvolatile memory device 2610 so that stored data is read from the nonvolatile memory device 2610 or data is stored therein in response to a read/write request from a host 2630.

According to an embodiment of the inventive concept, after the upper molding layer is formed on the upper package substrate, the extended regions ERs of the upper package substrate may be folded, patterned, or otherwise shaped so that the extended regions are positioned on and against the sides of the upper molding layer. In such embodiments, the ERs may form sidewalls. Therefore, the increase in the size of a semiconductor package may be prevented.

According to another embodiment of the inventive concept, a shielding layer can be formed on the lower surfaces of the extended regions of the upper package substrate. Therefore, electromagnetic waves emitted from the upper semiconductor chip may be shielded.

The foregoing is illustrative of embodiments and is not to be construed as necessarily limiting the scope of the inventive concept. Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims. Modifications to the disclosed embodiments, as well as other embodiments, are intended to be included within the scope of the appended claims.

What is claimed is:

1. A semiconductor package comprising:
a plurality of stacked semiconductor chips;
a molding layer covering side surfaces of the semiconductor chips; and
a package substrate comprising a chip region on which the semiconductor chips are mounted and an edge region covering a side surface of the molding layer,
wherein the package substrate comprises:
a first through-hole disposed in the chip region;
a second through-hole disposed in the edge region;
a first bonding pad disposed on the edge region, the first bonding pad being adjacent to the first through-hole; and
a second bonding pad disposed on the edge region, the second bonding pad being spaced apart from the first bonding pad, the second bonding pad being adjacent to the second through-hole,
wherein one of the semiconductor chips is connected to the second bonding pad by a second bonding wire, and a second pattern connected to the second bonding pad is extended to the second through-hole.

2. The semiconductor package of claim 1, wherein the other one of the semiconductor chips is connected to the first bonding pad by a first bonding wire, and a first pattern connected to the first bonding pad is extended to the first through-hole.

3. The semiconductor package of claim 1, wherein:
the edge region of the package substrate comprises an extended region and a bonding region disposed between the chip region and the extended region,
wherein the first bonding pad and the second bonding pad are disposed on the bonding region, and the second through-hole is disposed in the extended region.

4. The semiconductor package of claim 3, wherein a lower surface of the molding layer contacts an upper surface of the bonding region of the package substrate, and the side surface of the molding layer contacts a side surface of the extended region of the package substrate.

5. The semiconductor package of claim 3, wherein
the extended region of the package substrate comprises a first extended region and a second extended region,
wherein a side surface of the package substrate in the first extended region contacts the side surface of the molding layer, and an upper surface of the package substrate in the second extended region is spaced apart from the side surface of the molding layer.

6. The semiconductor package of claim 5, wherein a plane angle between an upper surface of the package substrate disposed in the bonding region and the side surface of the package substrate disposed in the first extended region ranges from about 45° to about 135°, and a plane angle between the side surface of the package substrate disposed in the first extended region and the upper surface of the package substrate disposed in the second extended region ranges from about 225° to 280°.

7. The semiconductor package of claim 5, wherein an upper surface of the molding layer covers the upper surface of the package substrate disposed in the second extended region.

8. The semiconductor package of claim 1, wherein a plane angle between an upper surface of the package substrate disposed in the chip region and a side surface of the package substrate disposed in the edge region ranges from about 45° to about 135°.

9. The semiconductor package of claim 1, wherein the edge region of the package substrate is extended onto an upper surface of the molding layer.

10. The semiconductor package of claim 1, wherein an upper surface of the molding layer has a width larger than that of a lower surface of the molding layer.

11. The semiconductor package of claim 1, further comprising a shielding layer disposed on a lower surface of the edge region of the package substrate.

12. The semiconductor package of claim 11, wherein the second pattern is electrically connected to the shielding layer through the second through-hole.

13. A semiconductor package comprising:
a lower package; and
an upper package comprising a plurality of upper semiconductor chips stacked on the lower package, an upper molding layer covering side surfaces of the upper semiconductor chips, and an upper package substrate having a chip region on which the upper semiconductor chips are mounted and an edge region covering a side surface of the upper molding layer,
wherein the package substrate comprises:
a first through-hole disposed in the chip region;
a second through-hole disposed in the edge region;
a first bonding pad disposed on the edge region, the first bonding pad being adjacent to the first through-hole; and
a second bonding pad disposed on the edge region, the second bonding pad being spaced apart from the first bonding pad, the second bonding pad being adjacent to the second through-hole, and
wherein one of the upper semiconductor chips is connected to the second bonding pad by a second bonding wire, and a second pattern connected to the second bonding pad is extended to the second through-hole.

14. The semiconductor package of claim 13, wherein the other one of the upper semiconductor chips is connected to the first bonding pad by a first bonding wire, and a first pattern connected to the first bonding pad is extended to the first through-hole.

15. The semiconductor package of claim 13, further comprising an interposer substrate disposed between the upper package substrate and the lower package substrate.

16. A semiconductor package, comprising:
a substrate comprising a chip region formed between two bonding regions, which are formed between two extended regions;
a plurality of stacked semiconductor chips in the chip region;
a plurality of boding pads formed in the bonding regions; and
a molding layer formed on the chip region and the boding regions, the molding layer covering side surfaces of the semiconductor chips,
wherein the extended regions cover side surfaces of the molding layer.

17. The semiconductor package of claim 16, wherein the substrate is an upper package substrate, the semiconductor package further comprising:
a lower package supporting the upper package substrate and comprising a lower package substrate having a plurality of external terminals; and
an interposer substrate disposed between the upper package substrate and the lower package substrate

18. The semiconductor package of claim 16, further comprising a shielding layer disposed on sides of the extended region.

19. The semiconductor package of claim 16, wherein a side surface of the extended region that contacts the molding layer is sloped.

20. The semiconductor package of claim 16, wherein a portion of the extended region covers a portion of the molding layer.
